(19) United States
(12) Patent Application Publication
(10) Pub. No.: US 2011/0316657 A1
(43) Pub. Date: Dec. 29, 2011

(54) Three Dimensional Wire Bond Inductor and Transformer

(75) Inventors: Sang-June Park, San Diego, CA (US); Jonghae Kim, San Diego, CA (US); Matthew M. Nowak, San Diego, CA (US); Steve C. Ciccarelli, San Diego, CA (US)

(73) Assignee: QUALCOMM Incorporated, San Diego, CA (US)

(21) Appl. No.: 12/824,955

(22) Filed: Jun. 28, 2010

(51) Int. Cl. H01F 5/00

(52) U.S. Cl. 336/200

(57) ABSTRACT

A three-dimensional inductor or transformer for an electronic packaging system that includes a plurality of conductive traces and a plurality of conductive wire bonds. The traces are located in a single layer, and each have a first and second pad. Each of the wire bonds couples the second pad of one trace to the first pad of another trace. The trace and wire bonds create a continuous conductive path from the first pad of a first trace to the second pad of a last trace. Passing a current from the first trace to the last trace creates an electromagnetic field between the single layer and the wire bonds. The transformer includes two independent and electromagnetically coupled inductors that can be interleaved. The continuous conductive path can be solenoid-shaped. A shielding layer can also be included that blocks the substrate from the electromagnetic field of the inductor or transformer.

### FIELD OF DISCLOSURE

The present disclosure relates generally to integrated circuit devices, and more particularly, to inductors and transformers implemented in integrated circuit devices.

### BACKGROUND

Inductors and transformers are used in a wide variety of integrated circuit applications including radio frequency (RF) integrated circuit applications. An inductor is a passive electrical component that can store energy in a magnetic field created by the current passing through it. An inductor can be a conductor shaped as a coil or solenoid which includes one or more “turns.” The turns concentrate the magnetic field flux induced by current flowing through each turn of the conductor in an “inductive” area within the inductor turns. The number of turns and the size of the turns affect the inductance.

Two (or more) inductors which have coupled magnetic flux form a transformer. A transformer is a device that transfers electrical energy from one circuit to another through inductively coupled conductors, usually the coils or turns of the inductors that form the transformer. A varying current in a first or “primary” inductor induces a varying voltage in a second or “secondary” inductor. If a load is coupled to the secondary inductor, a current will flow in the secondary inductor and electrical energy will flow from the primary circuit through the transformer to the load.

Conventional two-dimensional inductors, and transformers implemented therefrom, in integrated circuit dies and circuit packages can have several drawbacks. These inductors can be made by forming helical or spiral traces in conductive layers to form inductor turns. In some cases, these traces may be coupled to traces in adjacent layers in order to achieve higher inductance. These helical or spiral inductors require one conductive layer for the helical or spiral trace and another to bring the internal end of the helical or spiral trace to an output port. These inductors and transformers can consume excessive conductive layer resources and may not provide sufficient current capacity or high enough quality factor without undesirable scaling. In addition, because the inductive areas of the inductors are substantially parallel with respect to other trace layers in the package substrate and circuit die, they can have undesirable electromagnetic interference (EMI) effects on other components within the integrated circuit and/or their inductor characteristics can be adversely affected by adjacent conductors within the substrate or circuit die.

It would be desirable to have an inductor and transformer implementation where the inductor can create higher inductance values yet take up less space desirable for other components, and have less adverse EMI effects with other components.

### SUMMARY

A three-dimensional inductor for an integrated circuit system is disclosed. The three-dimensional inductor includes a plurality of conductive traces and a plurality of conductive wire bonds. The conductive traces are located in a single layer, and each of the conductive traces has a first pad and a second pad. Each of the conductive wire bonds couples the second pad of one of the conductive traces to the first pad of another of the conductive traces. The traces and wire bonds create a continuous conductive path from the first pad of a first conductive trace to the second pad of a last conductive trace. Passing a current through the continuous conductive path from the first pad of the first conductive trace to the second pad of the last conductive trace creates an electromagnetic field between the single layer and the conductive wire bonds.

The plurality of conductive traces can be substantially parallel. The first pads of the conductive traces can be substantially on a first line and the second pads of the conductive traces can be substantially on a second line, where the first line is substantially parallel to the second line.

The three-dimensional inductor can also include a substrate that is coupled to the single layer and is substantially parallel to the single layer: The substrate can be made of silicon, glass, sapphire, quartz or other material. The three-dimensional inductor can also include a shielding layer located between the single layer and the substrate, where the shielding layer blocks the substrate from the electromagnetic field between the single layer and the conductive wire bonds.

The three-dimensional inductor can also include a first port and a first port wire bond coupling the first port to the first pad of the first conductive trace. The three-dimensional inductor can also include a second port and a second port wire bond coupling the second port to the second pad of the last conductive trace.

The three-dimensional inductor can be integrated into various devices, including a set top box, an entertainment unit, a navigation device, a communications device, a personal digital assistant (PDA), a fixed location data unit, a mobile location data unit, a mobile phone, a cellular phone, a computer, a portable computer, a desktop computer, a monitor, a computer monitor, a television, a tuner, a radio, a satellite radio, a music player, a digital music player, a portable music player, a video player, a digital video player, a digital video disc (DVD) player, and a portable digital video player.

A three-dimensional transformer for an integrated circuit system is disclosed. The three-dimensional transformer includes a plurality of conductive traces and a plurality of conductive wire bonds that form a first and second inductor. The conductive traces are located in a single layer, and each of the conductive traces has a first pad and a second pad. Each of the conductive wire bonds couples the second pad of one of the conductive traces to the first pad of another of the conductive traces. The first inductor has a first port and a second port, and is formed by a first set of the plurality of conductive traces and a first set of the plurality of conductive wire bonds. The first sets of the plurality of conductive traces and conductive wire bonds forms a first continuous conductive path from the first port to the second port of the first inductor. The second inductor has a first port and an second port, and is formed by a second set of the plurality of conductive traces and a second set of the plurality of conductive wire bonds. The second sets of the plurality of conductive traces and conductive wire bonds forms a second continuous conductive path from the first port to the second port of the second inductor. The second continuous conductive path is independent of the first continuous conductive path. The first inductor is electromagnetically coupled to the second inductor. Passing a current through the first continuous conductive path creates an electromagnetic field between the single layer and the first set of wire bonds, and this electromagnetic field can induce a current in the second continuous conductive path. Passing a current through the second continuous conductive path creates an electromagnetic field between the single layer and the second set of wire bonds, and this electromagnetic field can induce a current in the first continuous conductive path.

The first continuous conductive path of the first inductor can be interleaved with the second continuous conductive path of the second inductor such that each conductive trace of the first set of conductive traces is adjacent to one of the conductive traces of the second set of conductive traces, and each wire bond of the first set of wire bonds is adjacent to one of the wire bonds of the second set of wire bonds. The plurality of conductive traces can be substantially parallel. The first pads of the conductive traces can be substantially on a first line, and the second pads of the conductive traces can be substantially on a second line, where the first line is substantially parallel to the second line.

The three-dimensional transformer can also include a substrate coupled to the single layer and substantially parallel to the single layer. The substrate can be made of silicon, glass, sapphire, quartz or other material. The three-dimensional transformer can also include a shielding layer located between the single layer and the substrate, where the shielding layer blocks the substrate from the electromagnetic field between the single layer and the plurality of conductive wire bonds.

The first port of the first inductor can be the first pad of one of the first set of conductive traces. The second port of the first inductor can be the second pad of one of the first set of conductive traces. The first port of the second inductor can be the first pad of one of the second set of conductive traces. The second port of the second inductor can be the second pad of one of the second set of conductive traces.

The first inductor can also include an input port and an input port wire bond coupling the input port to the first pad of one of the first set of conductive traces. The first inductor can also include an output port and an output port wire bond coupling the output port to the second pad of one of the first set of conductive traces. The second inductor can also include an input port and an input port wire bond coupling the input port to the first pad of one of the second set of conductive traces. The second inductor can also include an output port and an output port wire bond coupling the output port to the second pad of one of the second set of conductive traces.

The three-dimensional transformer can be integrated into various devices, including a set top box, an entertainment unit, a navigation device, a communications device, a personal digital assistant (PDA), a fixed location data unit, a mobile location data unit, a mobile phone, a cellular phone, a computer, a portable computer, a desktop computer, a monitor, a computer monitor, a television, a tuner, a radio, a satellite radio, a music player, a digital music player, a portable music player, a video player, a digital video player, a digital video disc (DVD) player, and a portable digital video player.

A three-dimensional inductor having a first port and a second port for use in integrated circuit devices is disclosed. The three-dimensional inductor includes a plurality of conductive layer means and a plurality of conductive non-layer means. The plurality of conductive layer means are located in a single layer of an integrated circuit, and each of the layer means has a first pad and a second pad that are in conductive contact. Each of the plurality of conductive non-layer means has a first end and a second end in conductive contact. The non-layer means are coupled to the single layer but are not in the single layer of the integrated circuit. The first end of each of the non-layer means is coupled to the second pad of one of the layer means, and the second end of each of the non-layer means is coupled to the first pad of another of the layer means. The plurality of layer means and non-layer means create a continuous conductive path from the first pad of a first layer means of the plurality of layer means to the second pad of a last layer means of the plurality of layer means. Passing a current through the continuous conductive path from the first pad of the first layer means to the second pad of the last layer means creates an electromagnetic field between the single layer and the plurality of conductive non-layer means.

The plurality of conductive layer means can be substantially parallel. The continuous conductive path can be substantially solenoid-shaped. The three-dimensional inductor can also include a shielding means and a substrate, where the shielding means is located between the single layer and the substrate, and the shielding means blocks the substrate from the electromagnetic field between the single layer and the plurality of conductive non-layer means.

A three-dimensional transformer for an electronic packaging system is disclosed. The three-dimensional transformer includes a plurality of conductive layer means and a plurality of conductive non-layer means that form a first and second inductor. The plurality of conductive layer means are in a single layer of an integrated circuit, and each of the layer means has a first pad and a second pad that are in conductive contact. Each of the plurality of conductive non-layer means has a first end and a second end that are in conductive contact. The plurality of non-layer means are coupled to the single layer but are not in the single layer of the integrated circuit. The first end of each of the non-layer means is coupled to the second pad of one of the layer means and the second end of each of the non-layer means is coupled to the first pad of another of the layer means. The first inductor has a first port and a second port, and is formed by a first set of the plurality of layer means and a first set of the plurality of non-layer means. The first sets of the plurality of layer means and non-layer means forms a first continuous conductive path from the first port to the second port of the first inductor. The second inductor has a first port and a second port, and is formed by a second set of the plurality of layer means and a second set of the plurality of non-layer means. The second sets of the plurality of layer means and non-layer means forms a second continuous conductive path from the first port to the second port of the second inductor. The second continuous conductive path is independent of the first continuous conductive path. Passing a current through the first continuous conductive path creates an electromagnetic field between the single layer and the first set of non-layer means, and passing a current through the second continuous conductive path creates an electromagnetic field between the single layer and the second set of non-layer means. The first inductor is electromagnetically coupled to the second inductor.

The first continuous conductive path of the first inductor can be interleaved with the second continuous conductive path of the second inductor such that each layer means of the first set of layer means is adjacent to one of the layer means of the second set of layer means, and each non-layer means of the first set of non-layer means is adjacent to one of the non-layer means of the second set of non-layer means. The first continuous conductive path and the second continuous conductive path can be substantially solenoid-shaped. The three-dimensional transformer can also include a substrate and a shielding layer located between the single layer and the substrate, where the shielding layer blocks the substrate from the electromagnetic field between the single layer and the plurality of conductive non-layer means.

For a more complete understanding of the present disclosure, reference is now made to the following detailed description and the accompanying drawings.

### BRIEF DESCRIPTION OF THE DRAWINGS

FIG. 1 is a schematic of a cross-section of a die for use in an electronic package;

FIG. 2 is a top-view of a two-dimensional spiral-shaped inductor;

FIG. 3 is a side-view of the two-dimensional spiral-shaped inductor of FIG. 2;

FIG. 4 is a top-view of a three-dimensional five-turn wire bond inductor;

FIG. 5 is a perspective-view of a three-dimensional five-turn wire bond inductor;

FIG. 6 is a top-view of a three-dimensional transformer implemented by two three-dimensional two-turn wire bond inductors;

FIG. 7 is a perspective-view of a JEDEC wire bond;

FIG. 8 is a perspective-view of a three-dimensional three-turn wire bond inductor;

FIG. 9 is a schematic of a cross-section of a die including a two-dimensional spiral inductor and a shielding layer for use in an electronic package;

FIG. 10 is a schematic of a cross-section of a die including a three-dimensional wire bond inductor and a shielding layer for use in an electronic package;

FIG. 11 is an exemplary integrated circuit system including a three-dimensional wire bond inductor;

FIG. 12 is a perspective view of a two-dimensional 1.5 turn spiral inductor;

FIG. 13 is a graph of inductance versus frequency and Q factor versus frequency for the two-dimensional 1.5 turn spiral inductor of FIG. 12;

FIG. 14 is a perspective view of a two-dimensional 2.5 turn spiral inductor;

FIG. 15 is a graph of inductance versus frequency and Q factor versus frequency for the two-dimensional 2.5 turn spiral inductor of FIG. 14;

FIG. 16 is a perspective view of a two-dimensional 3.5 turn spiral inductor;

FIG. 17 is a graph of inductance versus frequency and Q factor versus frequency for the two-dimensional 3.5 turn spiral inductor of FIG. 16;

FIG. 18 is a perspective-view of a three-dimensional two-turn wire bond inductor;

FIG. 19 is a graph of inductance versus frequency for six different wire bond radii for the three-dimensional two-turn wire bond inductor of FIG. 18;

FIG. 20 is a graph of Q factor versus frequency for six different wire bond radii for the three-dimensional two-turn wire bond inductor of FIG. 18;

FIG. 21 is a graph of inductance versus frequency for five different wire bond radii for a three-dimensional three-turn wire bond inductor;

FIG. 22 is a graph of Q factor versus frequency for five different wire bond radii for a three-dimensional three-turn wire bond inductor;

FIG. 23 is a graph of inductance versus frequency for five different wire bond radii for a three-dimensional four-turn wire bond inductor;

FIG. 24 is a graph of Q factor versus frequency for five different wire bond radii for a three-dimensional four-turn wire bond inductor;

FIG. 25 is a graph of inductance versus frequency for five different wire bond radii for a three-dimensional five-turn wire bond inductor;

FIG. 26 is a graph of Q factor versus frequency for five different wire bond radii for a three-dimensional five-turn wire bond inductor; and

FIG. 27 is a block diagram showing an exemplary wireless communication system in which a three-dimensional wire-bond inductor and/or transformer or other devices based thereon may be advantageously employed.

### DETAILED DESCRIPTION

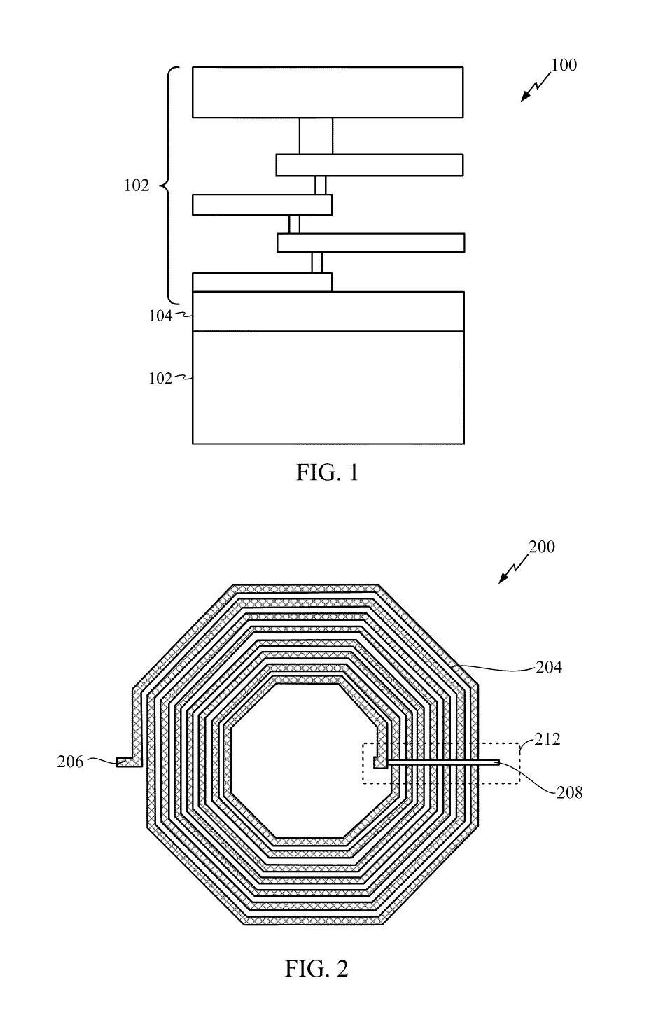

FIG. 1 shows a die 100 which includes a substrate 102, a device layer 104, and multiple back-end of line (BEOL) layers 106. The substrate 102 could be made of various substrate materials known in the art, for example silicon, glass, sapphire, quartz, etc. An inductor or transformer can be implemented in various layers of the die 100 including one or more of the BEOL layers 106 or the device layer 104.

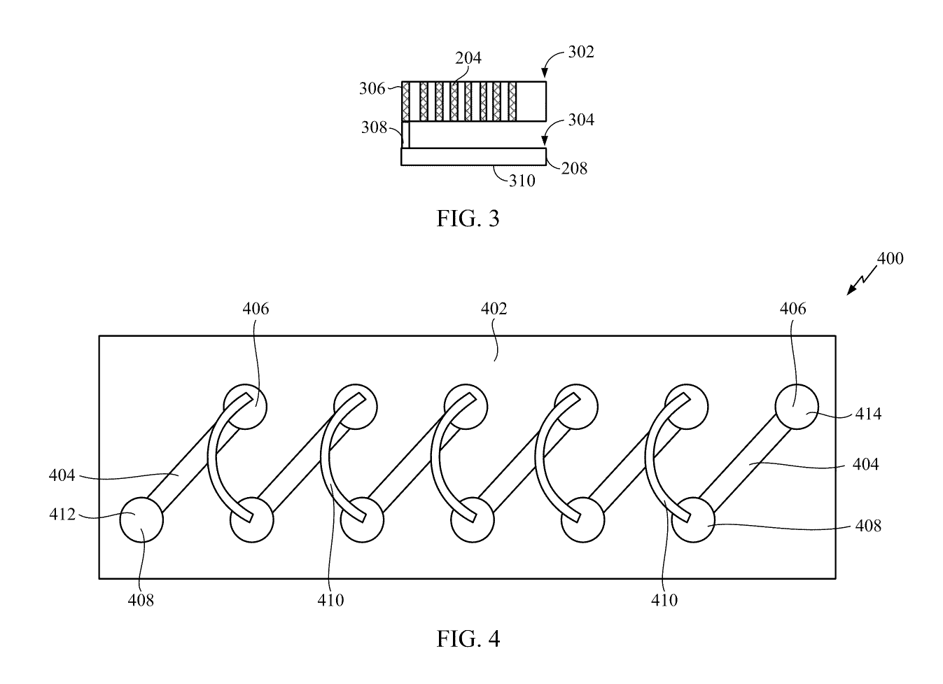

FIG. 2 illustrates a top-view of an exemplary two-dimensional inductor 200 comprising a spiral-shaped conductive path 204 extending from a first port 206 to a second port 208. FIG. 3 illustrates a cross-section of the portion of the two-dimensional inductor 200 enclosed in the dashed box 212. FIG. 3 shows that the spiral-shaped inductor 200 uses two layers, a first layer 302 and a second layer 304. The first layer 302 includes the spiral-shaped conductive path 204; however the spiral-shaped conductive path 204 has an internal end 306 that is not accessible on the first layer 302 because it is surrounded by the spiral-shaped conductive path 204. The second layer 304 is used to bring the internal end 306 of the spiral-shaped conductive path 204 to the exterior of the spiral-shaped conductive path 204. A connector 308 couples the internal end 306 of the spiral-shaped conductive path 204 to a proximal end of a trace 310 on the second layer 304, and the distal end of the trace 310 couples to the second port 208 of the inductor 200 which is on the exterior of the spiral-shaped conductive path 204. A second connector (not shown) between the first layer 302 and the second layer 304 can couple the distal end of the trace 310 to the second port 208, so that the second port 208 can also be on the first layer 302. In either case, the two-dimensional spiral inductor 200 requires two layers.

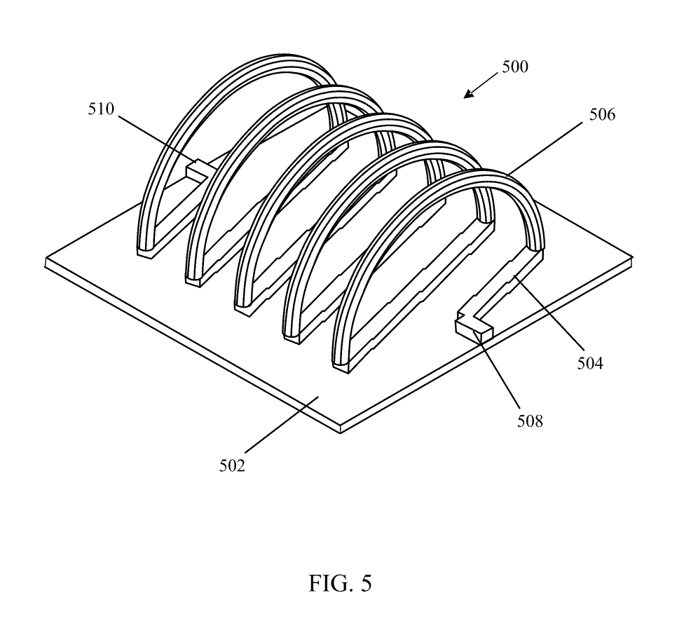

FIG. 4 illustrates a top-view of an exemplary three-dimensional wire bond inductor 400 on a layer 402 which can be a BEOL layer, a substrate or another layer in an electronic package. The three-dimensional wire bond inductor 400 comprises a plurality of conductive traces 404 and a plurality of wire bonds 410. Each trace 404 includes a first pad 406 and a second pad 408. The first pad 406 of the leftmost trace 410 can function as a first port 412 for the inductor 400, and the second pad 408 of the rightmost trace 404 can function as the second port 414 for the inductor 400. Each wire bond 410 couples the second pad 408 of one trace 404 to the first pad 406 of another trace 404. The exemplary three-dimensional inductor 400 has five loops formed by the wire bonds 410 and the metal traces 404 forming a continuous conductive path from the first port 412 to the second port 414. The continuous conductive path from the first port 412 to the second port 414 of the inductor 400 has a generally solenoid-like shape.

FIG. 5 illustrates a perspective-view of an exemplary three-dimensional inductor 500 on a layer 502. The three-dimensional inductor 500 comprises series of metal traces 504 and wire bonds 506 forming a continuous conductive path from a first port 508 to a second port 510 of the inductor 500. Like the inductor 400, the exemplary three-dimensional inductor 500 also has five loops formed by the wire bonds 506 and the metal traces 504 forming a solenoid-like shape. Of course, a three-dimensional inductor of this structure can have more or less loops as desired. Passing a current through the inductor 500 forms an electromagnetic field in the area between the wire bonds 506 and the layer 502. The wire bonds 510 can be made of various materials known in the art, for example gold, copper, silver, platinum, etc.

Note that the inductors 400 and 500 are implemented on a single layer with both the first and second ports of the inductors being accessible without the use of additional layers for connectors or bridges. The inductance of a wire bond inductor structured as shown in FIGS. 4 and 5 can be tuned in various ways. Some exemplary methods of tuning such a wire bond inductor include: changing the radius of the wire bonds, changing the thickness of the wire bonds, changing the length of the metal traces, changing the widths of the metal traces, and changing the spacing between the metal traces,

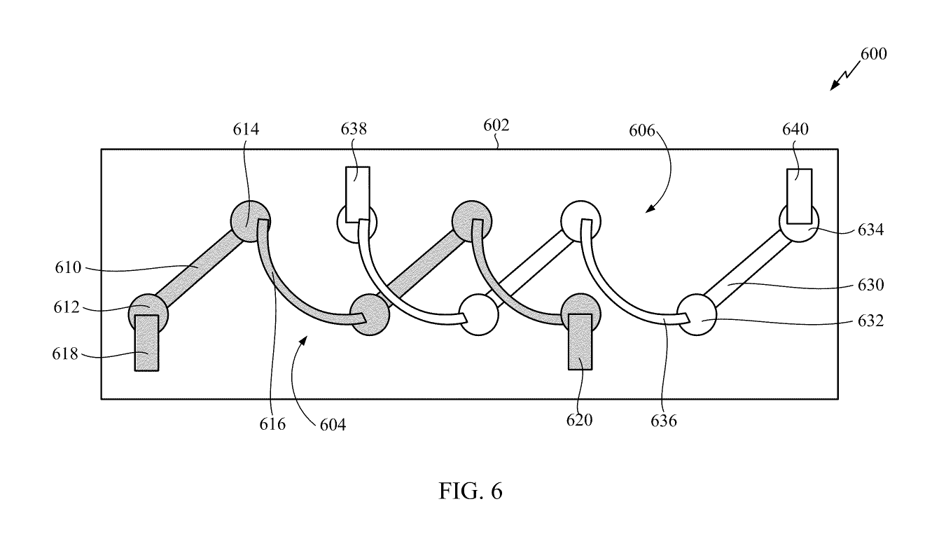

FIG. 6 illustrates a top-view of an exemplary three-dimensional transformer 600 on a layer 602. The three-dimensional transformer 600 comprises a first three-dimensional inductor 604 interleaved with a second three-dimensional inductor 606 to electromagnetically couple the first inductor 604 to the second inductor 606.

The first three-dimensional inductor 604 of the transformer 600 comprises a plurality of conductive traces 610 and a plurality of wire bonds 616 extending from a first port 618 to a second port 620. Each trace 610 includes a first pad 612 and a second pad 614. Each wire bond 616 couples the second pad 614 of one trace 610 to the first pad 612 of a next trace 610, or couples the second pad 614 of the rightmost trace 610 to the second port 620. The inductor 604 includes two loops formed by the wire bonds 616 and the traces 610 forming a continuous conductive path from the first port 618 to the second port 620. The continuous conductive path from the first port 618 to the second port 620 of the inductor 604 has a generally solenoid-like shape.

The second three-dimensional inductor 606 of the transformer 600 comprises a plurality of conductive traces 630 and a plurality of wire bonds 636 extending from a first port 638 to a second port 640. Each trace 630 includes a first pad 632 and a second pad 634. Each wire bond 636 couples the second pad 634 of one trace 630 to the first pad 632 of a next trace 630, or couples the first port 638 to the first pad 632 of the leftmost trace 630. The inductor 606 includes two loops formed by the wire bonds 636 and the metal traces 630 forming a continuous conductive path from the first port 638 to the second port 640. The continuous conductive path from the first port 638 to the second port 640 of the inductor 606 has a generally solenoid-like shape.

The conductive path of the first inductor 604 is interleaved with the conductive path of the second inductor 606 to form the transformer 600. Passing a current through the first inductor 604 forms an electromagnetic field in the area between the wire bonds 616 of the first inductor 604 and the substrate 602, which also includes the area between the wire bonds 636 of the second inductor 606 and the substrate 602. This electromagnetic field can induce a current in the second inductor 606; electromagnetically coupling the first inductor 604 to the second inductor 606 of the transformer 600.

Note that the transformer 600 is implemented on a single layer. The first and second ports 618, 620 of the first inductor 604, and the first and second ports 638, 640 of the second inductor 606 are all located on the substrate 602. The inductance of each of the inductors 604, 606 can be tuned to tune the transformer 600, as well as tuning by varying the turn ratio of the two inductors or other methods.

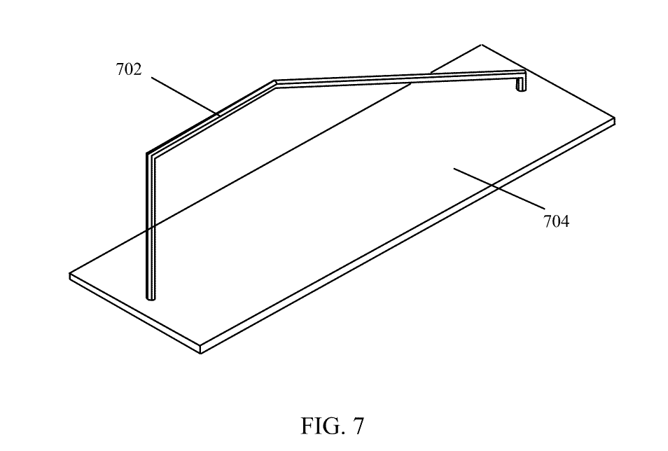

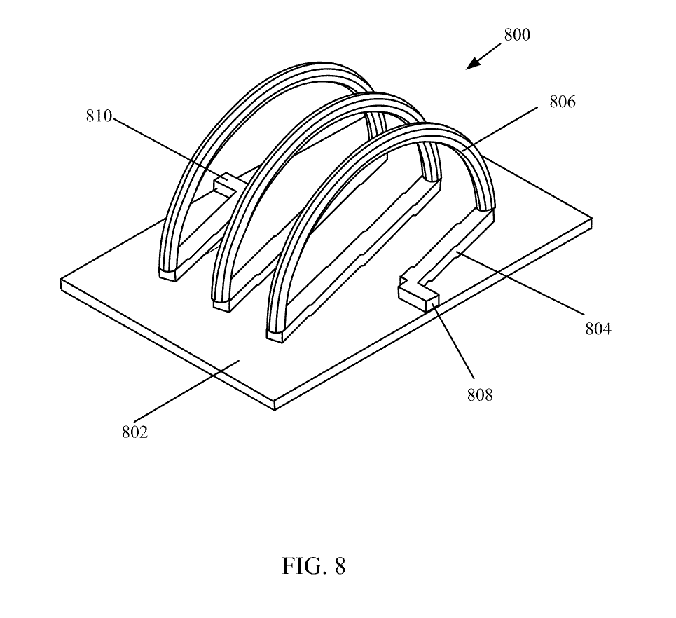

FIG. 7 illustrates a standard JEDEC wire bond 702 on a substrate 704. The wire bond 702 with dimensions of 1.5×0.03×0.5 mm̂3 at a frequency of 2 GHz has an inductance of 1.6 nH and a Q value of 45. The five turn wire bond inductor 500 with dimensions of 0.52×0.32×0.26 mm̂3 at a frequency of 2 GHz has an inductance of 4.0 nH and a Q value of 44. Thus, in a shorter and less high, but wider configuration, the three-dimensional inductor 500 provides 2.5 times the inductance with a similar Q value as the standard JEDEC wire bond 702.

FIG. 8 illustrates a perspective-view of an exemplary three-dimensional three-turn wire bond inductor 800 on a layer 802. The wire bond inductor 800 comprises a series of metal traces 804 and wire bonds 806 forming a continuous conductive path from a first port 808 to a second port 810 of the inductor 800. The inductor 800 is an embodiment of a three turn version of the five turn inductor 500. The three turn wire bond inductor 800 with dimensions of 0.32×0.32×0.26 mm̂3 at a frequency of 2 GHz has an inductance of 2.4 nH and a Q value of 42. Thus, in an even shorter configuration, the three-turn inductor 800 provides 1.5 times the inductance with a similar Q factor as the standard JEDEC wire bond 702.

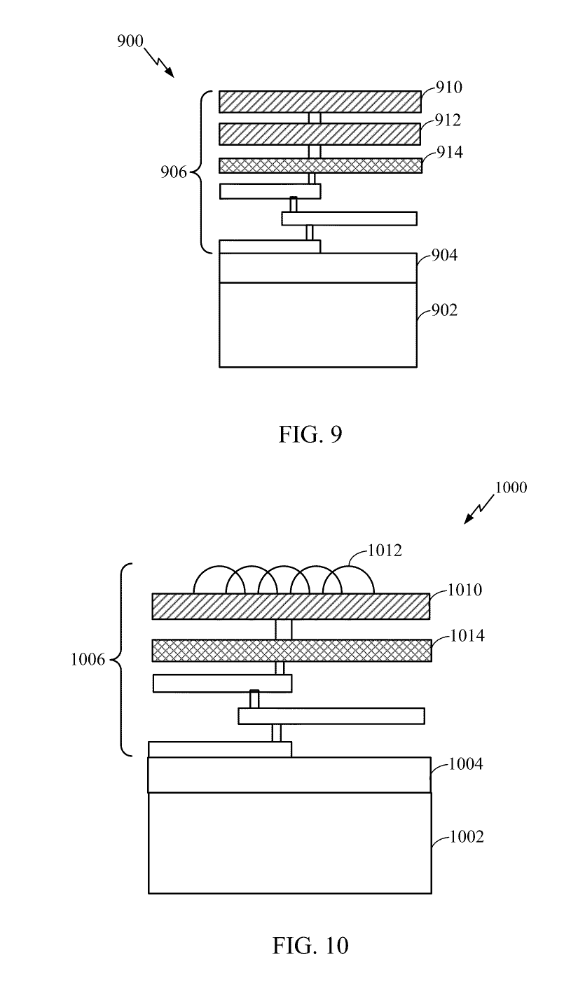

FIG. 9 illustrates an exemplary die 900 which includes a substrate 902, a device layer 904, and multiple back-end of line (BEOL) layers 906. In this embodiment, a conventional two-dimensional spiral inductor is implemented in the top two layers 910, 912 of the BEOL layers 906. One of the drawbacks of the conventional two-dimensional inductor is that the electromagnetic field it creates encompasses the BEOL layers 906 and the device layer 904 beneath the inductor. The electromagnetic interference (EMI) on these underlying layers makes them unusable for most purposes. A shielding layer 914 can be placed below the inductor layers 910, 912 to shield the underlying layers from the EMI. However, the shielding layer 914 interferes with the electromagnetic field of the inductor making it less effective.

FIG. 10 illustrates an exemplary die 1000 which includes a substrate 1002, a device layer 1004, and multiple back-end of line (BEOL) layers 1006. In this embodiment, a three-dimensional wire bond inductor or transformer, such as inductor 400, 500 or 800, or transformer 600 is implemented in the top BEOL layer 1010 using wire bonds 1012. The electromagnetic field created by the inductor or transformer is primarily between the top BEOL layer 1010 and the wire bonds 1012. A shielding layer 1014 can be placed below the top BEOL layer 1010 to shield the underlying BEOL layers and device layer 1004 from the EMI. Since the electromagnetic field created by the inductor or transformer is primarily above the top BEOL layer 1010, the shielding layer 1014 has little effect on the performance of the three-dimensional inductor or transformer. Thus a three-dimensional inductor layer 1010 can be implemented and the underlying BEOL layers and device layer 1004 can still be used by using an intervening shielding layer 1014 that does not interfere with the effectiveness of the three-dimensional inductor.

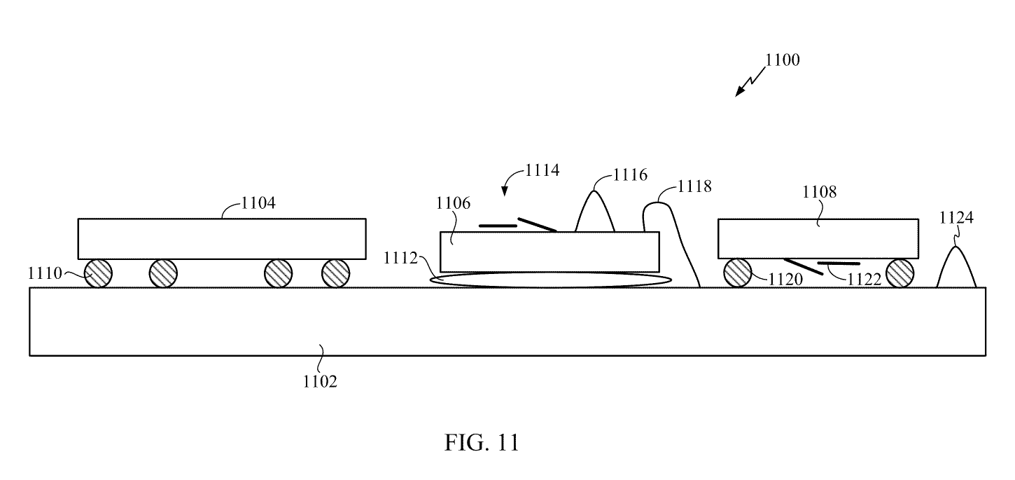

FIG. 11 illustrates an exemplary integrated circuit (IC) system 1100 that includes a system board 1102, a radio-frequency (RF) IC die 1104, a second die 1106 and a third die 1108. The RFIC die 1104 is mounted to the system board 1102 using solder balls 1110, the second die 1106 is mounted to the system board 1102 using an epoxy 1112 and the third die 1108 is mounted to the system board 1102 using solder balls 1120. The second die 1106 includes a capacitor/micro-electromechanical system (MEMS) device 1114 and a three-dimensional wire bond inductor 1116. A JEDEC inductor 1118 couples the second die 1106 to the system board 1102. The third die 1108 includes a capacitor/MEMS device 1122. A three-dimensional wire bond inductor 1124 is also implemented on the system board 1102. This exemplary IC system 1100 shows three-dimensional wire bond inductors 1116 and 1124 can be integrated into various layers of a system, including on a die or on a system board.

Experimental measurements were made to compare conventional two-dimensional spiral inductors with three-dimensional wire bond inductors.

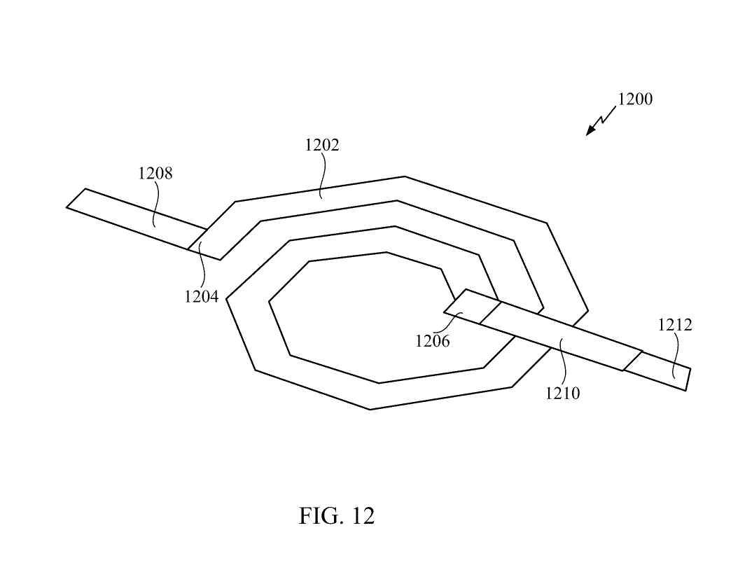

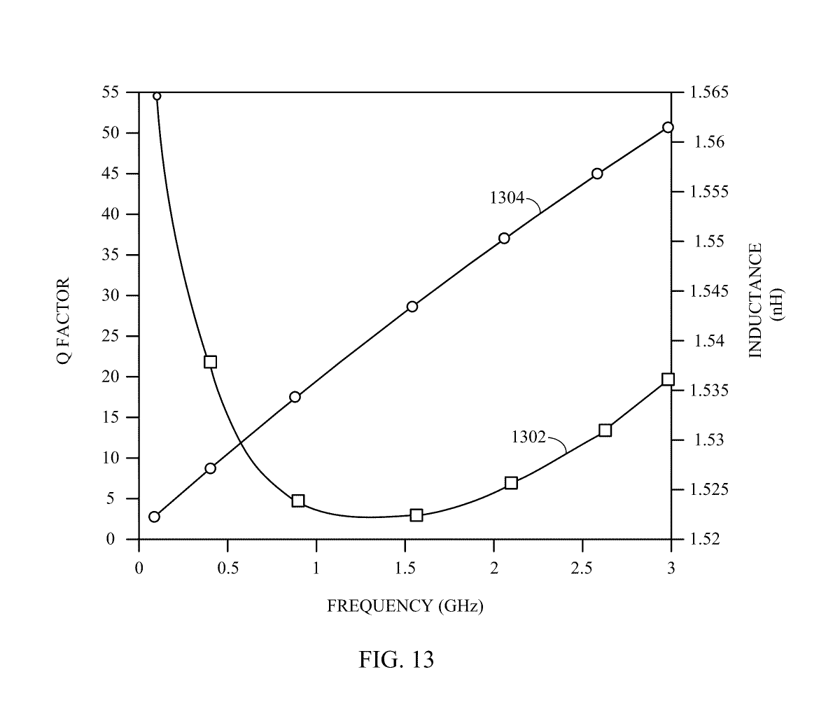

FIG. 12 illustrates a perspective-view of a conventional 1.5 turn two-dimensional spiral inductor 1200 on which measurements were collected. The spiral inductor 1200 is implemented using two layers. The spiral inductor 1200 comprises a conductive spiral portion 1202 extending from an interior end 1206 to an exterior end 1204 on a first layer. The exterior end 1204 is coupled to a first connector 1208 on the first layer. The interior end 1206 is coupled to a second connector 1212 by a bridge 1210 using a second layer to avoid contact between the bridge 1210 and any part of the spiral portion 1202 except for the interior end 1206. The spiral inductor 1200 had a size of 0.55 mm×0.5 mm (0.275 mm̂2), a conductor width of 50 μm and a gap width of 50 μm. FIG. 13 shows an inductance plot 1302 of inductance versus frequency and a Q plot 1304 of Q factor versus frequency for the spiral inductor 1200. At a frequency of 2 GHz, the spiral inductor 1200 has an inductance of 1.5 nH and a Q factor of 36.

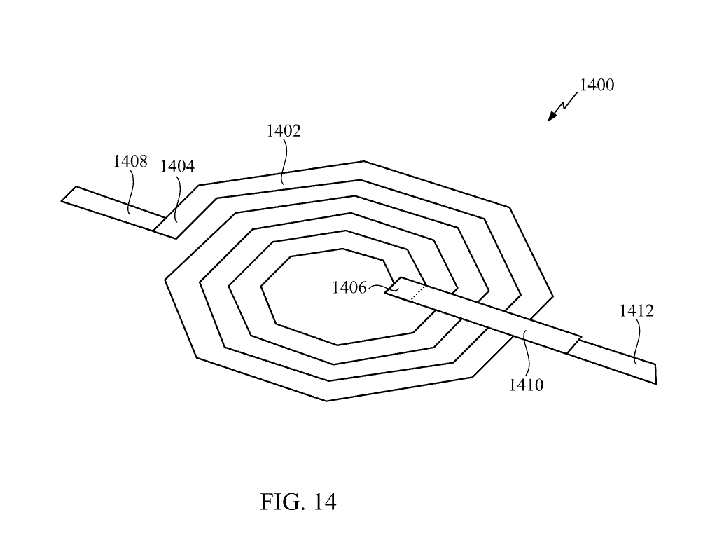

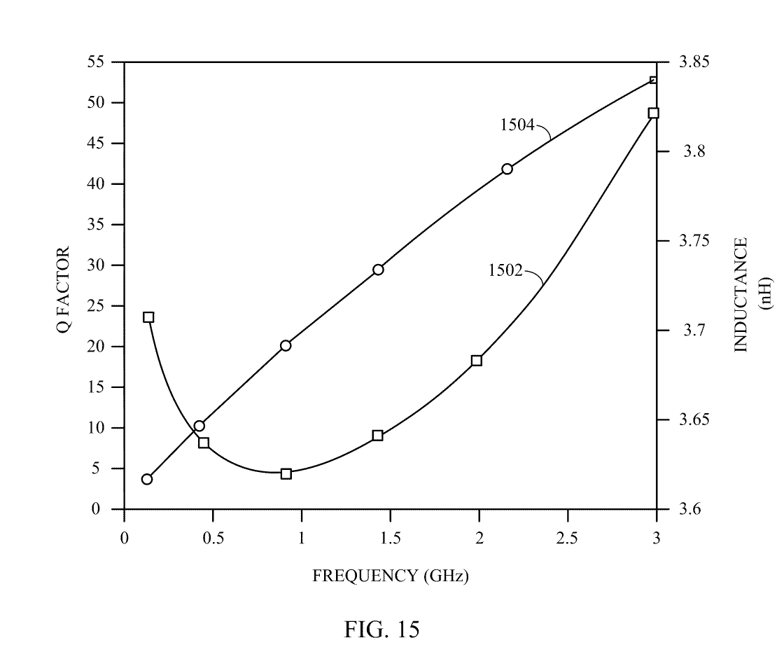

FIG. 14 illustrates a perspective-view of a conventional 2.5 turn two-dimensional spiral inductor 1400 on which measurements were collected. The spiral inductor 1400 is also implemented using two layers. The spiral inductor 1400 comprises a conductive spiral portion 1402 extending from an interior end 1406 to an exterior end 1404 on a first layer. The exterior end 1404 is coupled to a first connector 1408 on the first layer. The interior end 1406 is coupled to a second connector 1412 by a bridge 1410 using a second layer to avoid contact between the bridge 1410 and any part of the spiral portion 1402 except for the interior end 1406. The spiral inductor 1400 had a size of 0.75 mm×0.7 mm (0.525 mm̂2), a conductor width of 50 μm and a gap width of 50 μm. FIG. 15 shows an inductance plot 1502 of inductance versus frequency and a Q plot 1504 of Q factor versus frequency for the spiral inductor 1400. At a frequency of 2 GHz, the spiral inductor 1400 has an inductance of 3.7 nH and a Q factor of 39. Thus, the spiral inductor 1400 takes about twice the area of the spiral inductor 1200 and has almost 2.5 times the inductance at about the same Q factor.

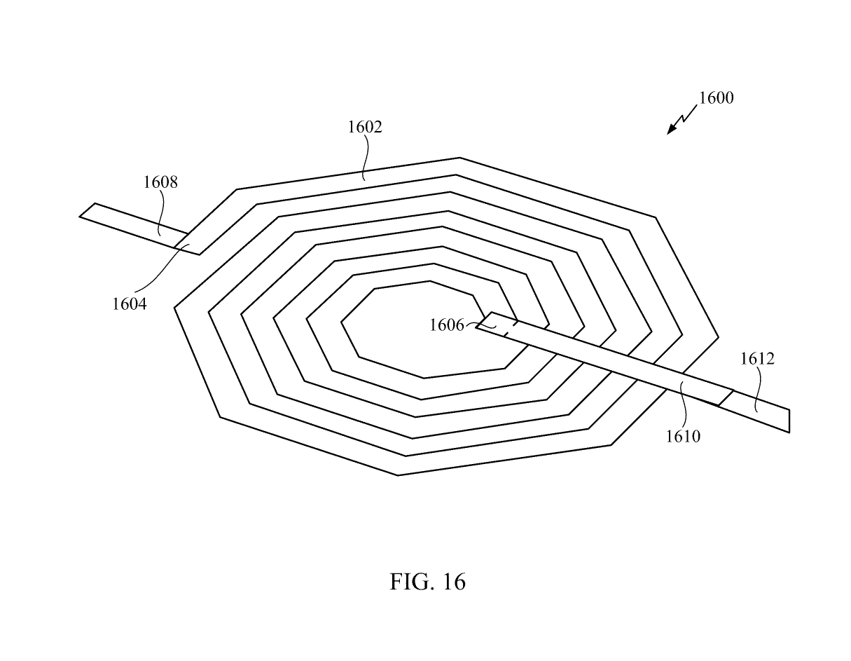

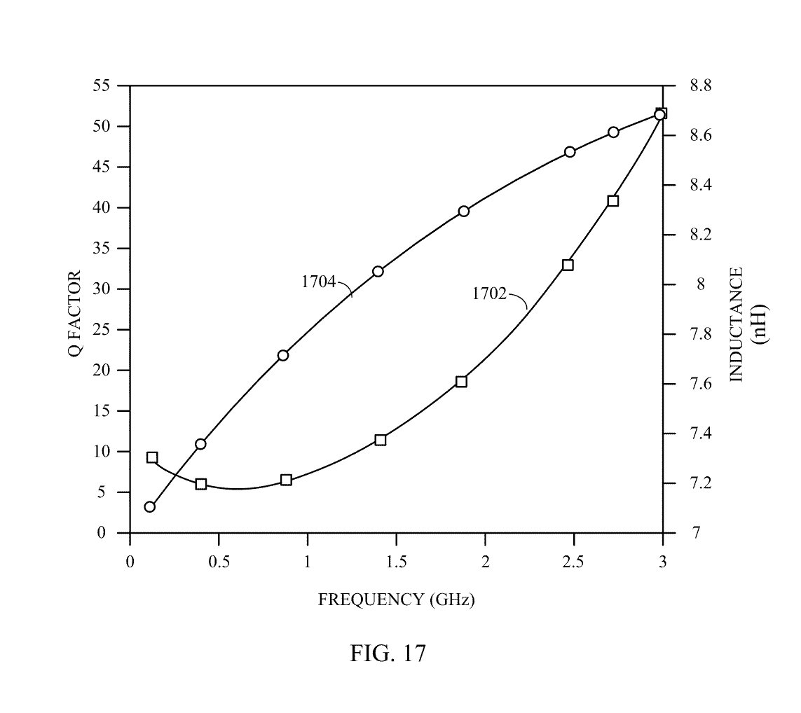

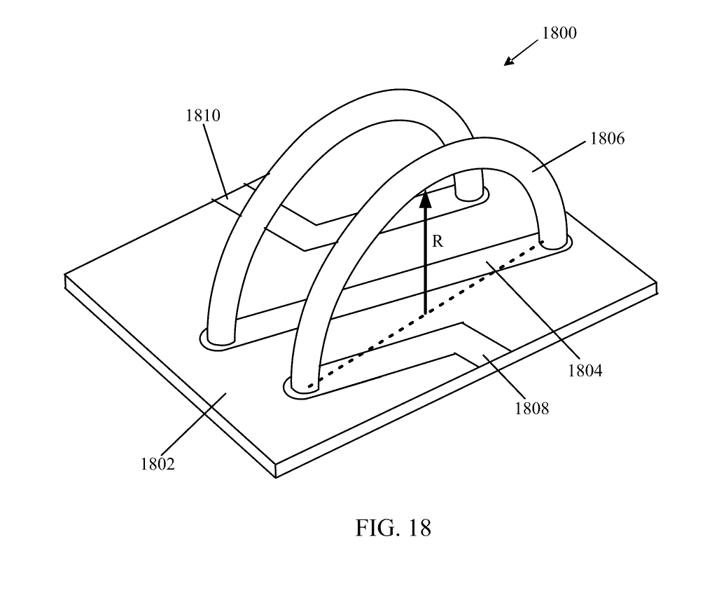

FIG. 16 illustrates a perspective-view of a conventional 3.5 turn two-dimensional spiral inductor 1600 on which measurements were collected. The spiral inductor 1600 is also implemented using two layers. The spiral inductor 1600 comprises a conductive spiral portion 1602 extending from an interior end 1606 to an exterior end 1604 on a first layer. The exterior end 1604 is coupled to a first connector 1608 on the first layer. The interior end 1606 is coupled to a second connector 1612 by a bridge 1610 using a second layer to avoid contact between the bridge 1610 and any part of the spiral portion 1602 except for the interior end 1606. The spiral inductor 1600 had a size of 0.98 mm×0.9 mm (0.882 mm̂2), a conductor width of 50 μm and a gap width of 50 μm. FIG. 17 shows an inductance plot 1702 of inductance versus frequency and a Q plot 1704 of Q factor versus frequency for the spiral inductor 1600. At a frequency of 2 GHz, the spiral inductor 1600 has an inductance of 7.7 nH and a Q factor of 42.

FIG. 18 illustrates a perspective-view of an exemplary three-dimensional wire bond inductor 1800 on a layer 1802. Unlike the two-dimensional spiral inductors described above, the three-dimensional wire bond inductor 1800 only requires one layer. The wire bond inductor 1800 comprises a series of metal traces 1804 and wire bonds 1806 forming a continuous conductive path from a first port 1808 to a second port 1810 of the inductor 1800. The metal traces 1804 form conductive layer means with substantially their entire length being in or on the layer 1802. The wire bonds 1806 form conductive non-layer means that are coupled to the layer 1802 at each end but with substantially their entire length not being in or on the layer 1802. The wire bond inductor 1800 is a two-turn wire bond inductor similar to the three-turn wire bond inductor 800 and the five-turn wire bond inductor 500. FIG. 18 also shows a radial parameter R characterizing the radius of the wire bonds 1806 from a center point on the layer 1802 between the two ends of the wire bond. The radial parameter R can be used to tune the inductor 1100. Three-dimensional wire bond inductors of this configuration were evaluated and some measurements are described below.

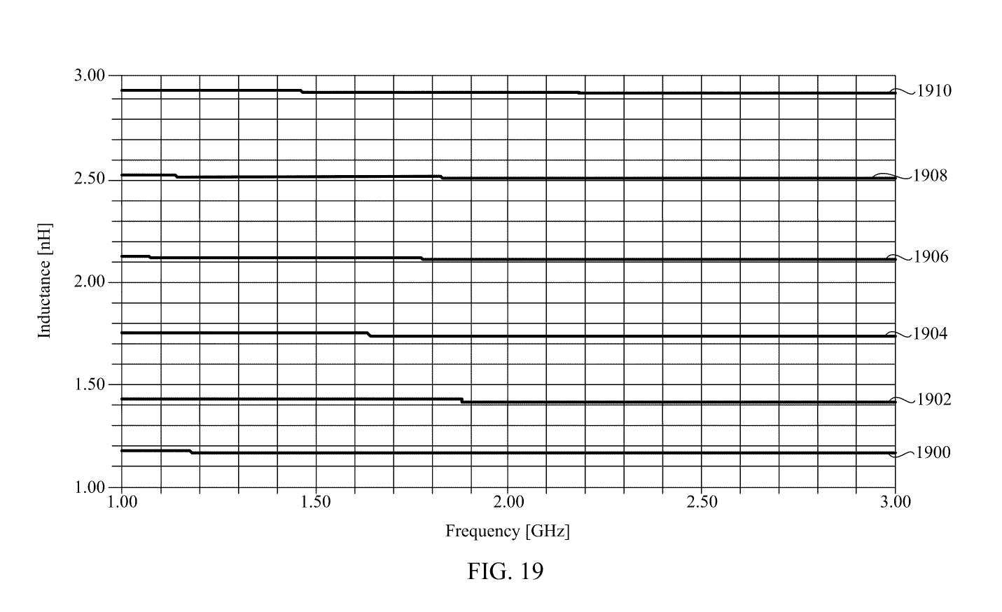

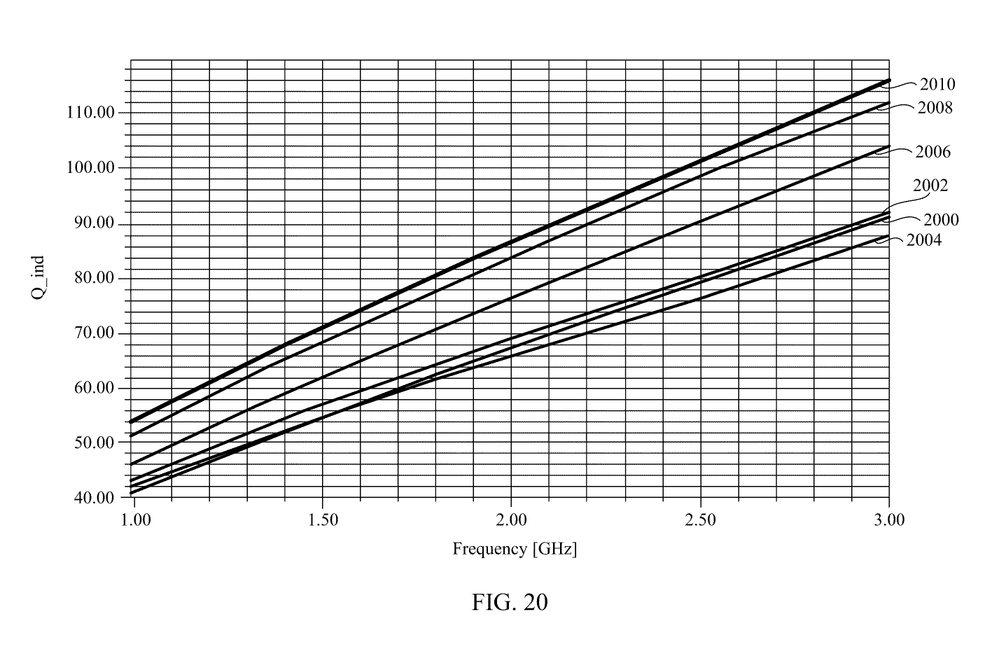

FIG. 19 includes plots of inductance versus frequency for the two-turn wire bond inductor 1800 for different radial parameters R, and FIG. 20 includes plots of Q factor versus frequency for the two-turn wire bond inductor 1800 for different radial parameters R. The measurements were taken on a substrate made of corning glass with a dielectric constant of 5.7, the traces 1804 were aluminum with a width of 3 μm and the wire bonds 1806 were gold with a thickness of 2 mils. The footprint of the wire bond inductor 1800 was 0.3 mm×0.6 mm (0.18 mm̂2), with the height dependent on the radial parameter R of the wire bonds. For the two-turn wire bond inductor 1800, FIG. 19 includes inductance plots 1900, 1902, 1904, 1906, 1908 and 1910, and FIG. 20 includes Q factor plots 2000, 2002, 2004, 2006, 2008 and 2010, for wire bond radius R of 0.15 mm, 0.2 mm, 0.25 mm, 0.3 mm, 0.35 mm and 0.4 mm, respectively. By changing the radius of the wire bonds from 015 mm to 0.4 mm, the inductance can be increased from approximately 1.2 nH to 2.9 nH. For a wire bond radius of 0.3 mm at 2 GHz, the wire bond inductor 1800 has an inductance of 2.1 nH and a Q factor of 77. Thus, with a smaller footprint than the 1.5 turn two-dimensional spiral inductor 1200 of FIG. 12, this embodiment of three-dimensional inductor 1800 provides 40% more inductance with double the Q factor at 2 GHz.

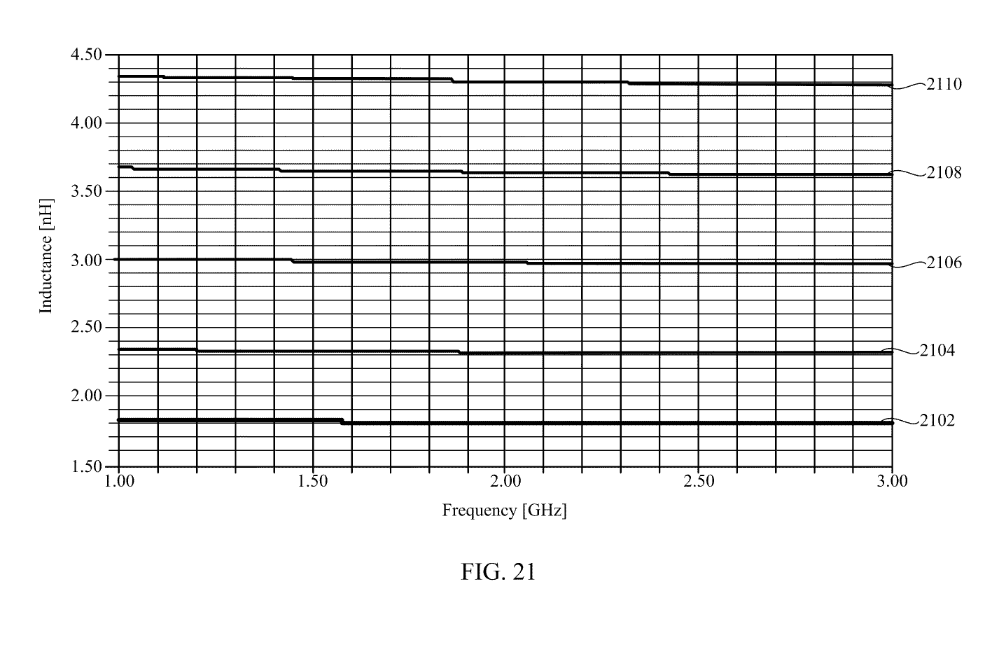

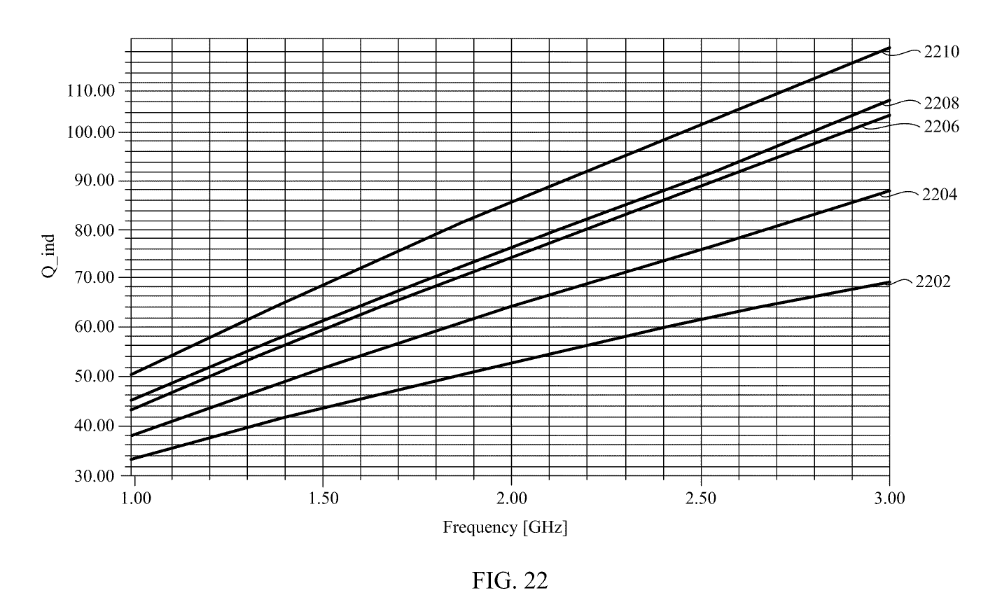

FIG. 21 includes plots of inductance versus frequency for a three-turn three-dimensional wire bond inductor, similar to wire bond inductor 800 of FIG. 8, for different radial parameters R, and FIG. 22 includes plots of Q factor versus frequency for the three-turn wire bond inductor for different radial parameters R. The measurements were taken on a substrate made of corning glass with a dielectric constant of 5.7, the traces were aluminum with a width of 3 μm and the wire bonds were gold with a thickness of 2 mils. The footprint of the inductor was 0.6 mm×0.6 mm (0.36 mm̂2), with the height dependent on the radial parameter R of the wire bonds. For the three-turn wire bond inductor, FIG. 21 includes inductance plots 2102, 2104, 2106, 2108 and 2110, and FIG. 22 includes Q factor plots 2202, 2204, 2206, 2208 and 2210, for wire bond radius R of 0.2 mm, 0.25 mm, 0.3 mm, 0.35 mm and 0.4 mm, respectively. By changing the radius of the wire bonds from 0.2 mm to 0.4 mm, the inductance can be increased from approximately 1.8 nH to 4.4 nH. The Q factor at 2 GHz ranges from a Q factor of 53 for 0.2 mm radius wire bonds to a Q factor of 86 for 0.4 mm radius wire bonds. For a wire bond radius of 0.3 mm at 2 GHz, the three-turn wire bond inductor has an inductance of 3.0 nH and a Q factor of 73. Thus, with a 30% larger footprint than the 1.5 turn two-dimensional spiral inductor 1200, this embodiment of the three-dimensional three-turn wire bond inductor provides twice the inductance with twice the Q factor at 2 GHz.

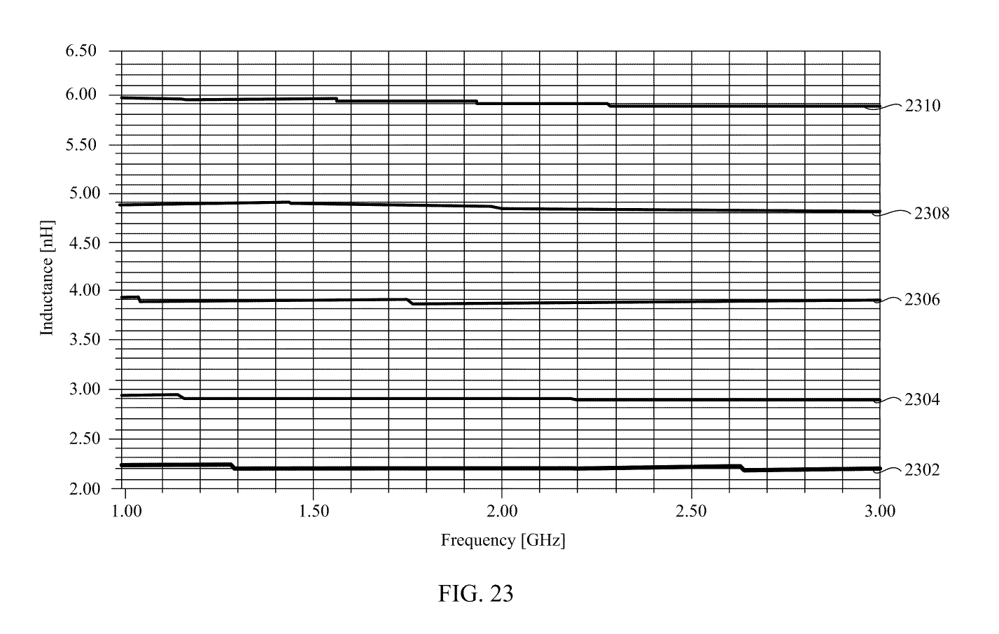

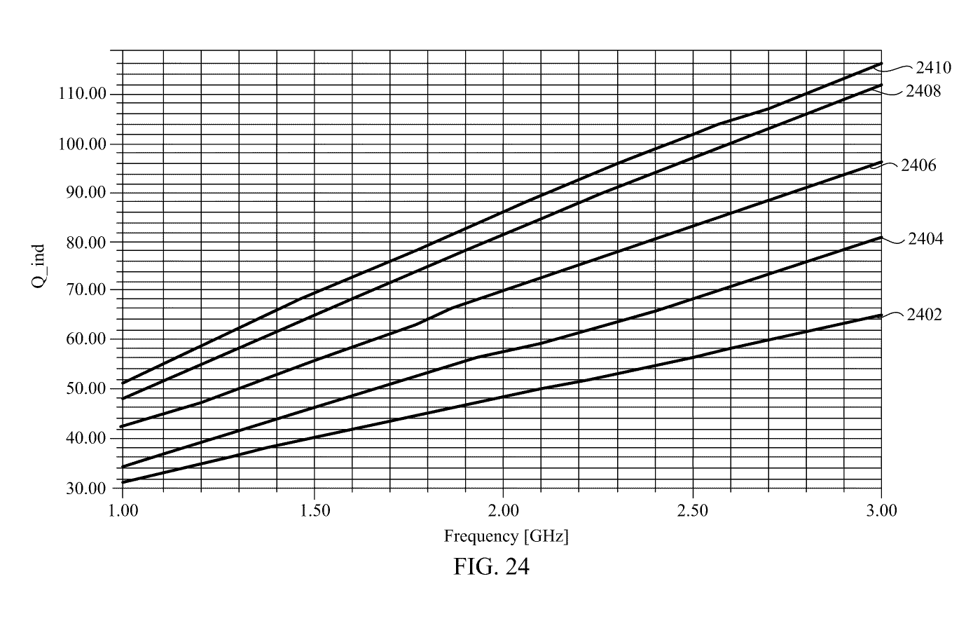

FIG. 23 includes plots of inductance versus frequency for a four-turn three-dimensional wire bond inductor for different radial parameters R, and FIG. 24 includes plots of Q factor versus frequency for the four-turn wire bond inductor for different radial parameters R. The measurements were taken on a substrate made of corning glass with a dielectric constant of 5.7, the traces were aluminum with a width of 3 μm and the wire bonds were gold with a thickness of 2 mils. The footprint of the inductor was 0.8 mm×0.6 mm (0.48 mm̂2), with the height dependent on the radial parameter R of the wire bonds. For the four-turn wire bond inductor, FIG. 23 includes inductance plots 2302, 2304, 2306, 2308 and 2310, and FIG. 24 includes Q factor plots 2402, 2404, 2406, 2408 and 2410, for wire bond radius R of 0.2 mm, 0.25 mm, 0.3 mm, 0.35 mm and 0.4 mm, respectively. By changing the radius of the wire bonds from 0.2 mm to 0.4 mm, the inductance can be increased from approximately 2.2 nH to 6.0 nH. The Q factor at 2 GHz ranges from a Q factor of 50 for 0.2 mm radius wire bonds to a Q factor of 90 for 0.4 mm radius wire bonds. For a wire bond radius of 0.3 mm at 2 GHz, the four-turn wire bond inductor has an inductance of 3.9 nH and a Q factor of 74. Thus, with a slightly smaller footprint than the 2.5 turn two-dimensional spiral inductor 1400, this embodiment of the three-dimensional four-turn wire bond inductor provides slightly more inductance with almost twice the Q factor at 2 GHz.

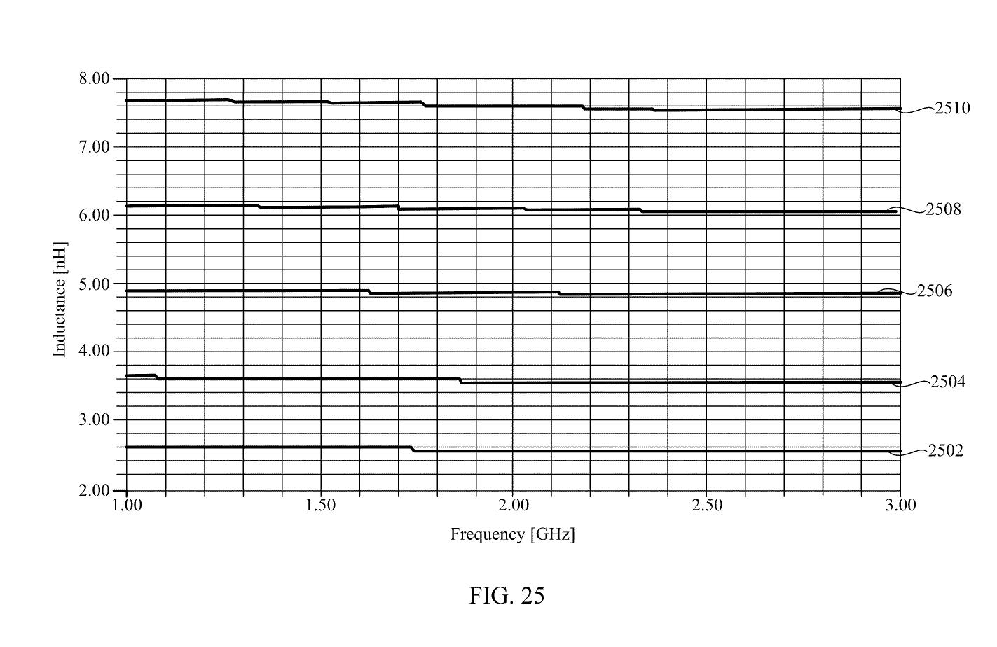

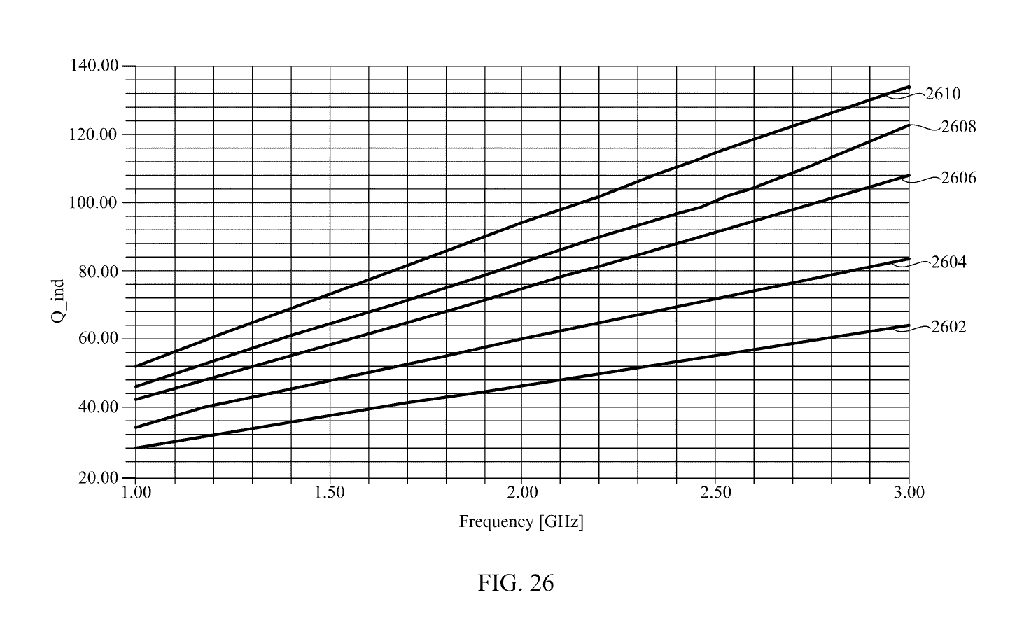

FIG. 25 includes plots of inductance versus frequency for a five-turn three-dimensional wire bond inductor, similar to the inductor 500 of FIG. 5, for different radial parameters R, and FIG. 26 includes plots of Q factor versus frequency for the five-turn wire bond inductor for different radial parameters R. The measurements were taken on a substrate made of corning glass with a dielectric constant of 5.7, the traces were aluminum with a width of 3 μm and the wire bonds were gold with a thickness of 2 mils. The footprint of the inductor was 1.0 mm×0.6 mm (0.6 mm̂2), with the height dependent on the radial parameter R of the wire bonds. For the five-turn wire bond inductor, FIG. 25 includes inductance plots 2502, 2504, 2506, 2508 and 2510, and FIG. 26 includes Q factor plots 2602, 2604, 2606, 2608 and 2610, for wire bond radius R of 0.2 mm, 0.25 mm, 0.3 mm, 0.35 mm and 0.4 mm, respectively. By changing the radius of the wire bonds from 0.2 mm to 0.4 mm, the inductance can be increased from approximately 2.6 nH to 7.6 nH. The Q factor at 2 GHz ranges from a Q factor of 47 for 0.2 mm radius wire bonds to a Q factor of 94 for 0.4 mm radius wire bonds. For a wire bond radius of 0.4 mm at 2 GHz, the five-turn wire bond inductor has an inductance of 7.6 nH and a Q factor of 94. Thus, with a smaller footprint than the 3.5 turn two-dimensional spiral inductor 1600, this embodiment of the three-dimensional five-turn wire bond inductor provides about the same inductance with more than twice the Q factor at 2 GHz.

Note that the inductance for the two-dimensional spiral inductors across the frequency range of 1.0 to 3.0 GHz (see FIGS. 13, 15, 17) is variable and non-linear. In contrast, the inductance for the three-dimensional wire bond inductors across the frequency range of 1.0 to 3.0 GHz (see FIGS. 19, 21, 23, 25) is almost constant. Note also that the Q factor for the two-dimensional spiral inductors across the frequency range of 1.00 to 3.00 GHz (see FIGS. 13, 15, 17) ranges from 20 to 55. In contrast, the Q factor for the three-dimensional wire bond inductors across the frequency range of 1.0 to 3.0 GHz (see FIGS. 20, 22, 24, 26) is significantly higher, ranging from 28 to over 120.

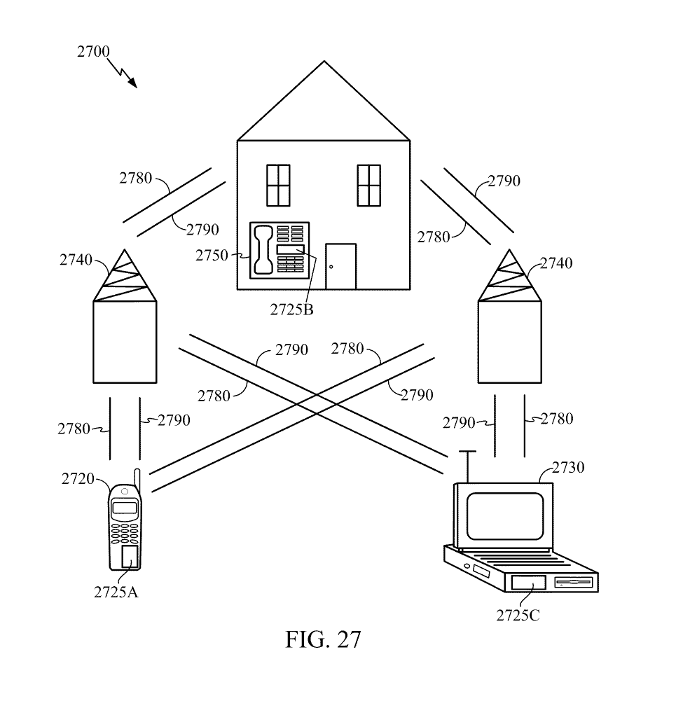

FIG. 27 shows an exemplary wireless communication system 2700 in which an embodiment of a wire bond inductor or transformer implemented by a plurality of conductive traces on a layer and coupling wire bonds to form a continuous conductive path may be advantageously employed. For purposes of illustration, FIG. 27 shows three remote units 2720, 2730, and 2750 and two base stations 2740. It should be recognized that typical wireless communication systems may have many more remote units and base stations. Any of remote units 2720, 2730, and 2750 may include a wire bond inductor or transformer as disclosed herein. FIG. 27 shows forward link signals 2780 from the base stations 2740 and the remote units 2720, 2730, and 2750 and reverse link signals 2790 from the remote units 2720, 2730, and 2750 to base stations 2740.

In FIG. 27, remote unit 2720 is shown as a mobile telephone, remote unit 2730 is shown as a portable computer, and remote unit 2750 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 27 illustrates certain exemplary remote units that may include wire bond inductors or transformers implemented as disclosed herein, the inductors and transformers implemented as disclosed herein are not limited to these exemplary illustrated units. Embodiments may be suitably employed in any electronic device in which inductors or transformers implemented by a plurality of conductive traces on a layer and wire bonds to form a continuous conductive path are desired.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A wire bond inductor for an integrated circuit system, the wire bond inductor comprising:
a plurality of conductive traces in a single layer, each of the plurality of conductive traces having a first pad in conductive contact with a second pad;
a plurality of conductive wire bonds, each of the plurality of conductive wire bonds coupling the second pad of one conductive trace of the plurality of conductive traces to the first pad of another conductive trace of the plurality of conductive traces, the plurality of conductive traces and the plurality of conductive wire bonds creating a continuous conductive path from the first pad of a first conductive trace of the plurality of conductive traces to the second pad of a last conductive trace of the plurality of conductive traces;
wherein passing a current through the continuous conductive path from the first pad of the first conductive trace to the second pad of the last conductive trace creates an electromagnetic field between the single layer and the plurality of conductive wire bonds.

2. The wire bond inductor of claim 1, wherein the plurality of conductive traces are substantially parallel.

3. The wire bond inductor of claim 1, wherein the first pads of the plurality of conductive traces are substantially on a first line, and the second pads of the plurality of conductive traces are substantially on a second line, the first line being substantially parallel to the second line.

4. The wire bond inductor of claim 1, further comprising a substrate coupled to the single layer, the substrate being substantially parallel to the single layer:

5. The wire bond inductor of claim 4, wherein the substrate is made of a material selected from silicon, glass, sapphire, and quartz:

6. The wire bond inductor of claim 4, further comprising a shielding layer located between the single layer and the substrate.

7. The wire bond inductor of claim 1, further comprising a first port and a first port wire bond coupling the first port to the first pad of the first conductive trace.

8. The wire bond inductor of claim 1, further comprising a second port and a second port wire bond coupling the second port to the second pad of the last conductive trace.

9. The wire bond inductor of claim 1, further comprising a device selected from the group consisting of a set top box, an entertainment unit, a navigation device, a communications device, a personal digital assistant (PDA), a fixed location data unit, a mobile location data unit, a mobile phone, a cellular phone, a computer, a portable computer, a desktop computer, a monitor, a computer monitor, a television, a tuner, a radio, a satellite radio, a music player, a digital music player, a portable music player, a video player, a digital video player, a digital video disc (DVD) player, and a portable digital video player, into which the wire bond inductor is integrated.

10. A wire bond transformer for an integrated circuit system, the wire bond transformer comprising:
a plurality of conductive traces in a single layer, each of the plurality of conductive traces having a first pad in conductive contact with a second pad;
a plurality of conductive wire bonds, each of the plurality of conductive wire bonds coupling the second pad of one conductive trace of the plurality of conductive traces to the first pad of another conductive trace of the plurality of conductive traces;
a first inductor having a first port and a second port; the first inductor including a first set of the plurality of conductive traces and a first set of the plurality of conductive wire bonds; the first sets of the plurality of conductive traces and conductive wire bonds forming a first continuous conductive path from the first port to the second port of the first inductor; and
a second inductor having a first port and an second port; the second inductor including a second set of the plurality of conductive traces and a second set of the plurality of conductive wire bonds; the second sets of the plurality of conductive traces and conductive wire bonds forming a second continuous conductive path from the first port to the second port of the second inductor, the second continuous conductive path being independent of the first continuous conductive path; and
wherein passing a current through the first continuous conductive path creates an electromagnetic field between the single layer and the first set of the plurality of wire bonds, and passing a current through the second continuous conductive path creates an electromagnetic field between the single layer and the second set of the plurality of wire bonds; the first inductor being electromagnetically coupled to the second inductor.

11. The wire bond transformer of claim 10, wherein the first continuous conductive path of the first inductor is interleaved with the second continuous conductive path of the second inductor such that each conductive trace of the first set of the plurality of conductive traces is adjacent to one of the conductive traces of the second set of the plurality of conductive traces, and each wire bond of the first set of the plurality of wire bonds is adjacent to one of the wire bonds of the second set of the plurality of wire bonds.

12. The wire bond transformer of claim 11, wherein the plurality of conductive traces are substantially parallel.

13. The wire bond transformer of claim 11, wherein the first pads of the plurality of conductive traces are substantially on a first line, and the second pads of the plurality of conductive traces are substantially on a second line, the first line being substantially parallel to the second line.

14. The wire bond transformer of claim 10, further comprising a substrate coupled to the single layer, the substrate being substantially parallel to the single layer:

15. The wire bond inductor of claim 14, wherein the substrate is made of a material selected from silicon, glass, sapphire, and quartz:

16. The wire bond transformer of claim 14, further comprising a shielding layer located between the single layer and the substrate, the shielding layer blocking the substrate from the electromagnetic fields between the single layer and the plurality of conductive wire bonds.

17. The wire bond transformer of claim 10, wherein the first port of the first inductor is the first pad of one of the first set of the plurality of conductive traces.

18. The wire bond transformer of claim 17, wherein the second port of the first inductor is the second pad of one of the first set of the plurality of conductive traces.

19. The wire bond transformer of claim 10, wherein the first port of the second inductor is the first pad of one of the second set of the plurality of conductive traces.

20. The wire bond transformer of claim 19, wherein the second port of the second inductor is the second pad of one of the second set of the plurality of conductive traces.

21. The wire bond transformer of claim 10, wherein the first inductor further comprises an input port wire bond coupling the first port of the first inductor to the first pad of one of the first set of the plurality of conductive traces.

22. The wire bond transformer of claim 21, wherein the first inductor further comprises output port wire bond coupling the second port of the first inductor to the second pad of one of the first set of the plurality of conductive traces.

23. The wire bond transformer of claim 10, wherein the second inductor further comprises an input port wire bond coupling the first port of the second inductor to the first pad of one of the second set of the plurality of conductive traces.

24. The wire bond transformer of claim 23, wherein the second inductor further comprises an output port wire bond coupling the second port of the second inductor to the second pad of one of the second set of the plurality of conductive traces.

25. The wire bond transformer of claim 10, further comprising a device selected from the group consisting of a set top box, an entertainment unit, a navigation device, a communications device, a personal digital assistant (PDA), a fixed location data unit, a mobile location data unit, a mobile phone, a cellular phone, a computer, a portable computer, a desktop computer, a monitor, a computer monitor, a television, a tuner, a radio, a satellite radio, a music player, a digital music player, a portable music player, a video player, a digital video player, a digital video disc (DVD) player, and a portable digital video player, into which the wire bond transformer is integrated.

26. A three-dimensional inductor having a first port and a second port for use in integrated circuit devices, the inductor comprising:
a plurality of conductive layer means in a single layer of an integrated circuit, each of the plurality of layer means having a first pad and a second pad in conductive contact;
a plurality of conductive non-layer means having a first end and a second end in conductive contact, the plurality of non-layer means coupled to the single layer but not in the single layer of the integrated circuit, the first end of each of the plurality of non-layer means being coupled the second pad of one of the plurality of layer means and the second end of each of the plurality of non-layer means being coupled to the first pad of another of the plurality of layer means, the plurality of layer means and the plurality of non-layer means creating a continuous conductive path from the first pad of a first layer means of the plurality of layer means to the second pad of a last layer means of the plurality of layer means;
wherein passing a current through the continuous conductive path from the first pad of the first layer means to the second pad of the last layer means creates an electromagnetic field between the single layer and the plurality of conductive non-layer means.

27. The three-dimensional inductor of claim 26, wherein the plurality of conductive layer means are substantially parallel.

28. The three-dimensional inductor of claim 26, wherein the continuous conductive path is substantially solenoid-shaped.

29. The three-dimensional inductor of claim 26, further comprising a shielding means and a substrate, the shielding means being located between the single layer and the substrate, the shielding means blocking the substrate from the electromagnetic field between the single layer and the plurality of conductive non-layer means.

30. A three-dimensional transformer for an electronic packaging system, the three-dimensional transformer comprising:
a plurality of conductive layer means in a single layer of an integrated circuit, each of the plurality of layer means having a first pad and a second pad in conductive contact;
a plurality of conductive non-layer means having a first end and a second end in conductive contact, the plurality of non-layer means coupled to the single layer but not being in the single layer of the integrated circuit, the first end of each of the plurality of non-layer means being coupled the second pad of one of the plurality of layer means and the second end of each of the plurality of non-layer means being coupled to the first pad of another of the plurality of layer means;
a first inductor having a first port and a second port; the first inductor being formed by a first set of the plurality of layer means and a first set of the plurality of non-layer means; the first sets of the plurality of layer means and non-layer means forming a first continuous conductive path from the first port to the second port of the first inductor; and
a second inductor having a first port and an second port; the second inductor being formed by a second set of the plurality of layer means and a second set of the plurality of non-layer means; the second sets of the plurality of layer means and non-layer means forming a second continuous conductive path from the first port to the second port of the second inductor, the second continuous conductive path being independent of the first continuous conductive path; and
wherein passing a current through the first continuous conductive path creates an electromagnetic field between the single layer and the first set of the plurality of non-layer means, and passing a current through the second continuous conductive path creates an electromagnetic field between the single layer and the second set of the plurality of non-layer means; the first inductor being electromagnetically coupled to the second inductor.

31. The three-dimensional transformer of claim 30, wherein the first continuous conductive path of the first inductor is interleaved with the second continuous conductive path of the second inductor such that each layer means of the first set of the plurality of layer means is adjacent to one of the layer means of the second set of the plurality of layer means, and each non-layer means of the first set of the plurality of non-layer means is adjacent to one of the non-layer means of the second set of the plurality of non-layer means.

32. The three-dimensional transformer of claim 30, wherein the first continuous conductive path and the second continuous conductive path are substantially solenoid-shaped.

33. The three-dimensional transformer of claim 30, further comprising a substrate and a shielding layer located between the single layer and the substrate; the shielding layer blocking the substrate from the electromagnetic field between the single layer and the plurality of conductive non-layer means.
